(19) United States
(12) Patent Application Publication
(10) Pub. No.: US 2005/0121226 A1
(43) Pub. Date: Jun. 9, 2005

(54) LAMINATES HAVING A LOW DIELECTRIC CONSTANT, LOW DISAPATION FACTOR BOND CORE AND METHOD OF MAKING SAME

(75) Inventors: Scott McKee, Brigham City, UT (US); Dave Luttrell, Phoenix, AZ (US); Mark Dhaenens, Chandler, AZ (US)

Correspondence Address: MCGARRY BAIR PC, 171 MONROE AVENUE, N.W., SUITE 600, GRAND RAPIDS, MI, 49503, US

(73) Assignee: PARK ELECTROCHEMICAL CORPORATION, Lake Success, NY (US)

(21) Appl. No.: 10/904,061

(22) Filed: Oct. 21, 2004

Related U.S. Application Data
(60) Provisional application No. 60/481,531, filed on Oct. 21, 2003.

(51) Int. Cl. H05K 1/02

(52) U.S. Cl. 174/259; 156/309.3

(57) ABSTRACT

Laminates have at least one resin-system layer, a low dielectric, low dissipation factor bond core having at least one surface that is treated for adhesion, such as by etching, plasma or Corona discharge or mechanical roughing to facilitate bonding to the at least one resin system layer and a conductive metal cladding on the at least one resin system layer. The bond core can be a fluoropolymer film or a fluoropolymer prepreg, having at least one etched or Corona discharge treated surface. Alternately, the bond core can be a polyetherimide film or a polyetherimide prepreg, having at least one etched or Corona discharge treated surface. The laminates are used, for example, high performance, low loss printed circuit boards. The laminates have the desired dielectric properties inherent to fluoropolymer materials and can be produced using conventional printed circuit board manufacturing processes, materials, and equipment. Methods of producing laminates are disclosed.

### CROSS REFERENCE TO RELATED APPLICATIONS

This application claims the benefit of U.S. Patent Application Ser. No. 60/481, 532, filed Oct. 21, 2003, which is incorporated herein by reference in its entirety.

### FIELD OF THE INVENTION

The invention relates to laminates having a low dielectric, low dissipation factor bond core for use, for example, in the manufacture of printed circuit boards. In one of its aspects, the invention relates to multi-layer fluoropolymer laminates. In another of its aspects, the invention relates to a fluoropolymer bond core for making multi-layer fluoropolymer laminates. In another of its aspects, the invention relates to a polyetherimide bond core for making multi-layer polyetherimide laminates. In yet another of its aspects, the invention relates to a method of making multi-layer fluoropolymer and polyetherimide laminates. In still another of its aspects, the invention relates to a method of making a fluoropolymer and polyetherimide bond core for use in the production of multi-layer low dielectric, low dissipation factor laminates. In yet another of its aspects, the invention relates to laminates that include low dielectric and low dissipation constants.

### DESCRIPTION OF THE RELATED ART

Fluoropolymer and polyetherimide film laminates are suitable for high performance, low loss printed circuit boards that are used in microwave telecommunications and high speed digital processing equipment applications. Polytetrafluoroethylene (PTFE) is typically used as the fluoropolymer film because of its unique properties, including its controlled and uniform dielectric constant and low loss factor across a wide temperature and frequency range and its good dimensional stability. Polyetherimide has similar dielectric and low loss factor properties. However, PTFE has a very low coefficient of friction and inherently does not bond well to other materials. As a result, multi-layer fluoropolymer laminates have not been successfully bonded together for use as a printed circuit board having suitable peel strength using conventional printed circuit board bonding equipment and techniques.

Taconic Advanced Dielectric Division of Taconic has disclosed in a web-based article entitled, “A Low Loss PTFE-Based Bond Ply Material For Multi-Layer PCB Applications” and in U.S. Pat. No. 6,500,529 and U.S. Patent Application Publication No. 2003/0072929, both entitled “Low Signal Loss Bonding Ply for Multi-layer Circuit Boards,” a PTFE-based bonding ply comprising a fluoropolymer/substrate composite and a thermosetting resin disposed on or impregnated into the fluoropolymer composite layer. The substrate in the composite can be woven fabrics, non-woven fabrics, and polymeric films. The bonding ply is used to laminate a plurality of printed circuit board layers. The thermosetting resin functions as an adhesive that holds the printed circuit boards together.

### SUMMARY OF THE INVENTION

According to the invention, a laminate comprises a low dielectric, low dissipation factor bond core and a resin-system layer for use in manufacturing flexible or rigid laminates that can be used in, for example, printed circuit boards. The low dielectric, low dissipation factor bond core can be a fluoropolymer or polyetherimide film or a fluoropolymer or polyetherimide prepreg, which is a reinforcement material, such as woven fiberglass or other similar fiber, impregnated with a fluoropolymer or polyetherimide. At least one, and preferably two, surfaces of the low dielectric, low dissipation factor bond core are etched or plasma or Corona discharge treated to facilitate bonding to the resin-system layer to form a low dielectric, low dissipation factor laminate. The polyetherimide core can also be a polyetherimide film or layer that is used in the manufacture of printed circuit boards, for example, a ULTEM® polyetherimide made by GE Plastics. Both of these bond core materials are characterized by low dielectric constant (Dk) and low dissipation factor (Df) properties. The bond core materials will typically have a dielectric constant less than 4.0, preferably below 3.0 and a dissipation factor less than 0.01, preferably less than 0.006.

The resin-system layer can be any suitable resin material employed in conventional processes for manufacturing printed circuit boards. The resin-system layer can be, for example, a conventional thermosetting prepreg, which, in turn, can be bonded to conductive foil layers that are bonded to a bond core layer to form the printed circuit board laminate. Alternatively, the resin-system layer can be a resin-coated conductive foil, which is directly bonded to the fluoropolymer or polyetherimide bond core to form the printed circuit board laminate. The resin system coating can be filled or unfilled with organic or inorganic fillers. A plurality of individual printed circuit boards can be bonded with a fluoropolymer bond core and, in the case where the resin-system layer is a conventional thermosetting prepreg, conventional thermosetting prepregs between each printed circuit board to form a multi-ply printed circuit board.

The resin-system layer can be any suitable resin used for the manufacture of printed circuit boards, typically but not limited to, epoxy resins. Suitable resins for use in the invention are sold by Park Nelco under the trade designation N4103, N4105, N4203, and N₄₂₀₅. Other suitable resins are disclosed in the US Patent to Ishii et al., U.S. Pat. No. 5,435,877, which is incorporated herein by reference. These resins can be filled or unfilled with inorganic or organic materials. Further, the resin-system can be reinforced or unreinforced with conventional woven and non-woven fabrics.

The fluoropolymers used in the fluoropolymer layer are preferably non-elastomeric fluoropolymers, and the most commonly used fluoropolymer is polytetrafluoroethylene (PTFE). Suitable compositions include polyvinylidene fluoride and copolymers of vinylidene fluoride with at least one monomer selected from the group consisting of hexafluoropropylene and tetrafluoroethylene. Preferred non-elastomeric fluoropolymers are tetrafluoroethylene polymers, including polytetrafluoroethylene, copolymers of tetrafluoroethylene and hexafluoropropylene, copolymers of tetrafluoroethylene and perfluoro(alkyl vinyl) ethers, and copolymers of tetrafluoroethylene and ethylene. Copolymers of ethylene and chlorotrifluoroethylene can also be employed.

In one embodiment of the invention, at least one surface, and preferably both surfaces, of the fluoropolymer (or polyetherimide?) bond core is treated during an etching process for facilitation of bonding between the fluoropolymer bond core and the resin-system layer of the fluoropolymer laminates. The etch composition used in the process can be any suitable fluoropolymer etching composition, such as FluoroEtche manufactured by Action Technologies. See Action Technologies product literature entitled “FluoroEtch®” published on the Action Technologies website and in the article entitled “The Etching of Fluoropolymers In Preparation for Bonding” also published on the Action Technologies website and dated Jun. 27, 2002.

Alternatively, plasma treatment or Corona discharge treatment with conventional processes can be used for treating the at least one surface, and preferably two surfaces, of the fluoropolymer and polyetherimide bond core for bonding with the resin-system layer.

Still further according to the invention, a method for making a printed circuit board laminate comprises the steps of treating at least one surface, and preferably two surfaces, of a low dielectric, low dissipation factor bond core layer to render it receptive to bonding to a resin-system layer and thereafter applying a resin-system layer to the treated surface of the low dielectric, low dissipation factor bond core layer under sufficient heat and pressure to bond the resin-system layer to the low dielectric, low dissipation factor bond core layer.

In a preferred embodiment of the invention, the resin-system layer has a conductive metal cladding layer laminated thereto. Preferably, the at least one resin-system layer is an epoxy prepreg. In another embodiment, the at least one resin-system layer is a resin-coated conductive foil.

In a preferred embodiment of the invention, the low dielectric, low dissipation factor bond core layer comprises a fluoropolymer or polyetherimide material.

In another embodiment of the invention, the treating step includes passing the fluoropolymer or bond core layer through a bath of a solution which attacks the fluorine in the polymer, whereby the fluorine is stripped from the surface of the fluoropolymer bond core layer and replaced with at least one of hydroxyl, carbonyl, and carboxyl groups.

In yet another embodiment, the treating step comprises applying to the at least one surface a plasma treatment. In another embodiment, the treating step comprises applying to the at least one surface a Corona discharge. In another embodiment of the invention step comprises mechanically brushing the surface of the low dielectric, low dissipation factor bond core layer.

In a preferred embodiment of the invention, the fluoropolymer bond core is a fluoropolymer film. Preferably, the fluoropolymer film is polytetrafluoroethylene.

In another embodiment, the fluoropolymer bond core is a fluoropolymer impregnated prepreg. Preferably, the fluoropolymer impregnated prepreg is impregnated with polytetrafluoroethylene.

### BRIEF DESCRIPTION OF THE DRAWINGS

FIG. 1 is an enlarged sectional view of a low dielectric, low dissipation factor bond core according to a first embodiment of the invention.

FIG. 2 is an exploded sectional view of a single low dielectric, low dissipation factor laminate having a bond core according to a second embodiment of the invention.

FIG. 3 is an enlarged sectional view of a multi-layer laminate comprising several single low dielectric, low dissipation factor laminates of FIG. 2.

FIG. 4 is an exploded sectional view of a single low dielectric, low dissipation factor laminate having a low dielectric, low dissipation factor bond core according to a third embodiment of the invention.

FIG. 5 is an enlarged sectional view of a multi-layer low dielectric, low dissipation factor laminate comprising several single low dielectric, low dissipation factor laminates of FIG. 4.

FIG. 6 is a schematic representation of a method for manufacturing the low dielectric, low dissipation factor bond core of FIG. 1.

FIG. 7 is a schematic representation of an alternate process for making the low dielectric, low dissipation factor bond core of FIG. 1.

### DESCRIPTION OF THE PREFERRED EMBODIMENT

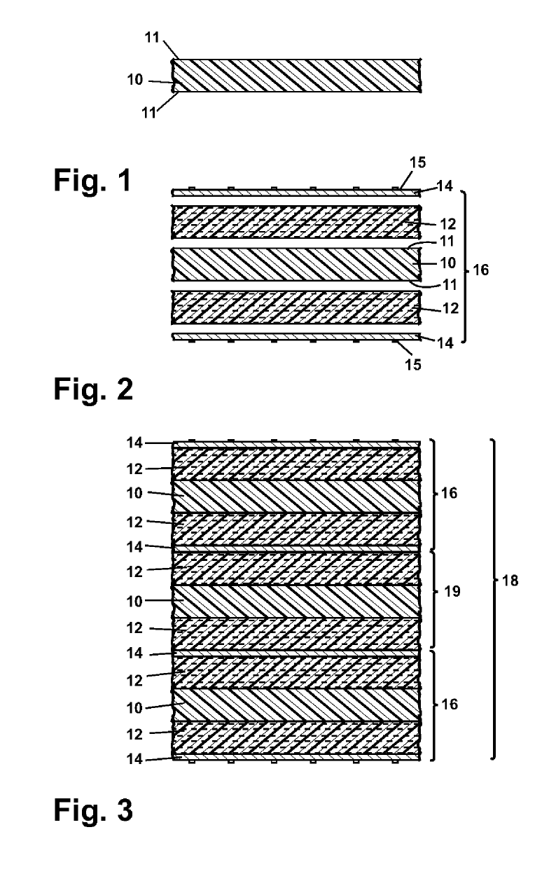

Referring now to the drawings and to FIG. 1 in particular, a low dielectric, low dissipation factor bond core comprises a fluoropolymer or polyetherimide film 10 having at least one and preferably two etched surfaces 11. Alternatively, the bond core can comprise an etched prepreg, which is a reinforcement that is preimpregnated with matrix resin, in this case preferably a fluoropolymer, usually in an uncured (“A” stage) or a partially cured (“B” stage) state. The reinforcement can be any suitable fiber, preferably woven fiberglass, used in the manufacture of prepregs for printed circuit board laminates.

The etching process, which will be described in detail hereinafter, alters the surface properties of the fluoropolymer film 1 0 to improve adhesion of the fluoropolymer film 1 0 to other components of printed circuit board laminates. Referring now to FIG. 2, a metal clad fluoropolymer laminate 16 comprises the etched fluoropolymer film 10 of FIG. 1 and further includes on the upper and lower sides thereof intermediate layers 12 having a lower processing temperature and pressure resin. Inclusion of the resin-system intermediate layers 12 permits the metal clad fluoropolymer laminates 16 to be processed at lower temperatures and pressures while incorporating the desirable dielectric properties of the fluoropolymer material. The intermediate layers 12 can be, for example, standard prepregs having a resin matrix preferably cured to “B” stage or “A” stage. Conductive foil layers 14 are further disposed on the upper and lower sides of the intermediate layers 12. Conductive foil layers 14 each have an etched outer surface 15. Thus, the metal clad fluoropolymer laminate 16 comprises an etched fluoropolymer film 10, intermediate layers 12, and etched conductive layers 14. In this second embodiment, the etched fluoropolymer film 10 serves as a bond core for the metal clad laminate 16. FIG. 2 is shown in exploded view for purposes of illustration but the layers 10, 12, and 14 are ultimately bonded together to form a metal clad laminate board 16.

The thickness of the intermediate layers 12 can vary over a wide range but generally are in the in range of 1.5 mils to 59 mils, with typical thicknesses in the range of 3 to 10 mils.

The laminates according to FIG. 2 are made by pressing at elevated temperatures the etched fluoropolymer film 10 between the intermediate layers 12 and the conductive foil layers 14 with conventional metal cladding equipment. The etched surface 11 of the film 10 assists in bonding the intermediate layers 12/conductive foil layers 14 to the film 10. The process employs conventional metal cladding equipment typically used for bonding metal foil layers to a standard resin prepreg. The conductive foil layers 14 are etched in conventional masking and etching processes typical in the manufacture of printed circuit boards.

Referring now to FIG. 3, a multi-layer fluoropolymer laminate assembly 18 comprises multiple single metal clad fluoropolymer laminates 16 with bond core laminates 19 therebetween. The bond core laminates 19 comprise etched fluoropolymer film 10 and intermediate layers 12. In the bond core laminates 19, the etched surface 11 assists in bonding the intermediate layers 12 to the fluoropolymer film 10. The intermediate layers 12 of the bond core laminates 19 bond to the metal clad fluoropolymer laminates 16.

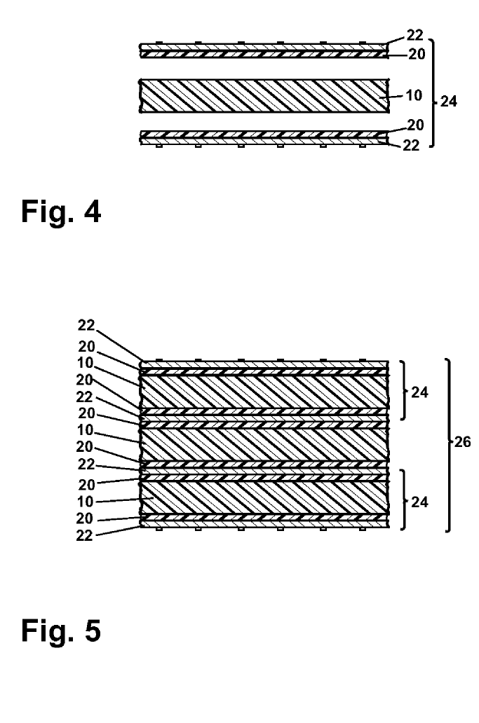

FIG. 4 illustrates a third embodiment of the invention, wherein a metal clad fluoropolymer laminate 24 comprises the etched fluoropolymer film 10 of the first and second embodiments and conductive foils 22, for example copper foils, on the upper and lower sides thereof. The conductive foils 22 have at least one side coated with a thin resin layer 20 and form a resin-system layer for this embodiment. The etched surface 11 of the film 10 bonds with the resin coating 20 on the conductive foil 22. As in the second embodiment, the resin coating 20 is preferably cured to the “B” stage or the “A” stage. Similar to FIG. 2, FIG. 4 is shown in exploded view for purposes of illustration but the layers 10 and 22 are ultimately bonded together to form a metal clad laminate board 24. In this embodiment, the intermediate layers 12 and the conductive foil layers 14 are effectively replaced with resin-coated conductive foils 22. The resin coatings can be any of the thermosetting resins used for the manufacture of printed circuit boards. Suitable resins that can be used in the resin coating 20 are disclosed in the US Patent to Ishii et al., U.S. Pat. No. 5,435,877, which is incorporated herein by reference. The thickness of the resin coating can vary over a wide range but is generally in the range of 0.5 to 10, preferably in the range of 1 to 2, and most preferably about 2.

The laminates according to FIG. 4 are made by pressing under heat the etched fluoropolymer film 10 between the resin-coated conductive foils 22 with conventional metal cladding equipment. The etched surface 11 of the film 10 assists in bonding the conductive foil layers 22 to the film 10 by means of the resin layer 20. The process employs conventional metal cladding equipment typically used for bonding metal foil layers to a standard resin prepreg. The conductive foil layers 22 are etched in conventional masking and etching processes typical in the manufacture of printed circuit boards.

Referring now to FIG. 5, a multi-layer fluoropolymer laminate assembly 26 comprises multiple metal clad fluoropolymer laminates 24 with etched fluoropolymer films 10 between each metal clad fluoropolymer laminate 24. In this configuration, the conductive foils 22 that have the fluoropolymer film 10 on each side thereof comprises the resin coated layer 20 on both sides of the conductive foil 22. The fluoropolymer film 10 between each metal clad fluoropolymer laminate 24 bonds to the conductive foils 22 of the metal clad fluoropolymer laminates 24 by means of the interaction between the etched surfaces 11 and the resin coated layers 20.

The fluoropolymer bond core according to the invention can be any fluoropolymer, preferably non-elastic, which has a controlled dielectric constant and a low loss characteristic required for printed circuit boards, particularly those suitable for use in microwave and high speed digital applications. These fluoropolymers include polytetrafluoroethylene (PTFE), fluorinated perfluoroethylene-propylene (FEP), perfluoroalkoxyalkane (PFA), and ethylenetetrafluoroethylene (ETFE), as well as other well-known fluorinated polymers or other reinforced or non-reinforced low dielectric, low dissipation factor material. The fluoropolymer can be in film form or as a matrix for the fiber filled prepreg. Generally, the fluoropolymer layer is relatively thin and flexible. The fluoropolymer layer is typically in the range of 1 mil or thinner and 7-8 mils or thicker.

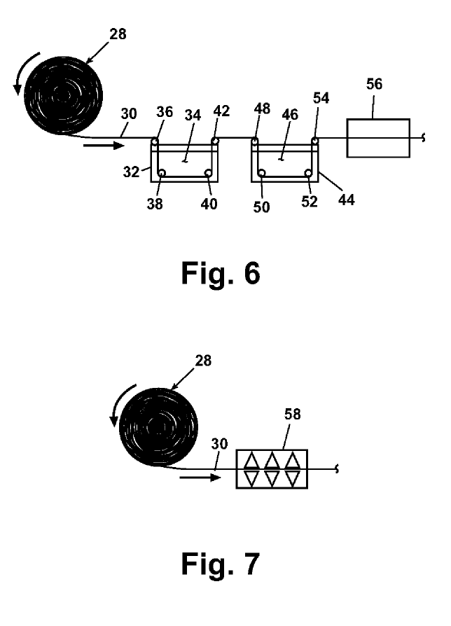

Referring now to FIG. 6, a process is disclosed for manufacture of the bond core, either the etched low dielectric, low dissipation factor bond core film 10 or the etched low dielectric, low dissipation factor bond core prepreg, according to one embodiment of the invention. A low dielectric, low dissipation factor bond core film roll 28 is mounted for rotation about a central axis and has a low dielectric, low dissipation factor bond core film 30 that is dispensed from the roll 28 and fed through an etching solution bath 32. The film 30 is drawn over idler rolls 36, 38, 40, and 42 at a suitable speed to etch both surfaces of the low dielectric, low dissipation factor bond core film 30. To this end, the etching solution bath 32 contains a suitable etch solution 34. The etch solution 34 is typically a sodium solution which attacks the fluorine in the polymer, but the etch composition can be any suitable fluoropolymer etching composition. For example, a suitable etch solution 34 is FluoroEtch®, which is manufactured by Action Technologies. In the etch process, the fluorine is stripped from the surface of the fluoropolymer film 30 and replaced with hydroxyl, carbonyl, and carboxyl groups. These groups are the organic species responsible for the adhesion of the fluoropolymer film 30 to the other components, such as the intermediate layers 12 or the resin-coated conductive films 20, of the laminates. Typically, a thirty to sixty second exposure to warm etching solution (50-60° C.) is sufficient for the etch process. Agitation of the film 30 in the etching bath 32 may enhance the etching process. The treated film 30 can be washed in an isopropyl or methyl alcohol bath, followed by a wash in hot water with detergent, rinsing, and drying.

Thus, the etched film 30, after withdrawal from the etch solution 34, is then passed through a series of wash and rinse baths 44, including an alcohol wash bath, a hot water and detergent bath, and a rinse bath, all of which are represented by the numeral 44, each of which has a cleaning solution. The first bath is an alcohol bath, the second bath is a hot water and detergent bath, and the third bath is a rinse bath. Any of the baths can be replaced by a sprayer for spraying the washing solution on the upper and lower surfaces of the treated film 30. After the film 30 has been thoroughly cleaned, it is passed through a dryer 56 at which it is dried.

Alternatively, mechanical roughening of the film surface can also be achieved using standard brushing machines in a roll to roll process. In addition, plasma etch in a roll to roll process can be used by using a CF₄/O₂ gas mixture or other.

An alternative method for manufacturing the low dielectric, low dissipation factor bond core according to the invention is depicted in FIG. 7, where like numerals reference like components. In this process, plasma treatment equipment 58 has been substituted for the etch bath 32, washing bath 44, and dryer 56. Similar to the etching process described above, the plasma treatment method alters the surface of the fluoropolymer or other bond core, whether the film 10 or prepreg, to facilitate bonding thereof to other laminate layers.

The etched low dielectric, low dissipation factor bond core according to the invention can be used as prepregs or laminate substrates and sold to customers for metal cladding and metal etching or can be used for making printed circuit boards as illustrated in FIGS. 2 and 4. Further, the etched low dielectric, low dissipation factor bond core according to the invention can be used in making multi-ply laminates as illustrated in FIGS. 3 and 6.

Testing has shown that sufficient bonding occurs between the etched surface of the fluoropolymer bond core and other laminate layers in the metal clad laminates and the multi-ply laminates, thus eliminating the need for additional bonding layers, such as thermosetting resins and the like, on the surface of the fluoropolymer film or prepreg. As a result, the process requires fewer steps and smaller quantities of material, which corresponds to an overall reduction in manufacturing cost. The method to manufacture printed circuit boards using an etched fluoropolymer bond core is simple and incorporates already existing resin systems, such as the standard prepreg and the resin-coated conductive foils. Furthermore, the etched fluoropolymer film or prepreg tends to exhibit greater thermal resistance when compared to resin-coated fluoropolymer bond plied. Additionally, the printed circuit boards and multi-ply laminates according to the invention are excellent for laser drilling and for boards that require a flexible laminate. Due to the excellent dielectric properties of the fluoropolymer material, these multi-layer boards can be used for a variety of applications that require high speed and low loss characteristics. The laminates according to the invention exhibit low dust drilling and minimal resin spots.

### EXAMPLES

Three samples according to the invention as described above with respect to FIG. 2 were made using an etched fluoropolymer bond core comprising a PTFE film laminate core thickness of 0.020, 0.030 and 0.060 inches. A Nelco N4000-13 epoxy resin prepreg was laminated to the PTFE film. The PTFE film was subjected to chemical etching and was followed by lamination to the N4000-13 epoxy resin under standard lamination conditions and with standard lamination equipment.

Two additional samples according to the invention as described above with respect to FIG. 2 were made using an etched polyetherimide bond core comprising a polyetherimide film with a thickness of 10 mils. A Nelco N4000-12 epoxy resin prepreg of 10 mils was laminated to each side of one of the polyetherimide films. A Nelco N4000-13 epoxy resin prepreg of 10 mils was laminated to each side of other of the polyetherimide films. The polyetherimide films were subjected to chemical etching followed by lamination to the Nelco N4000-12 and Nelco N4000-13 epoxy resin prepregs under standard lamination conditions and with standard lamination equipment.

The printed laminates thus produced were subjected to electrical property testing and pressure cooker solder float tests, and the results of these experiments are illustrated in Table 1.

TABLE 1

| | | | | | PRESSURE |
|---|---|---|---|---|---|
| | | | | | COOKER |
| | DIELECTRIC | DIELECTRIC | | | SOLDER |
| | CONSTANT | CONSTANT | DISSIPATION | DISSIPATION | FLOATS |
| | (DK) | (DK) | FACTOR (DF) | FACTOR (DF) | AVE. TIME TO |
| SAMPLE DESCRIPTION | 1 MHz | 10 GHz | 1 MHz | 10 GHz | FAILURE |
| PTFE | 3.15 | 3.17 | 0.0045 | 0.0056 | 494 |
| Core thickness = 0.030″ | | | | | seconds |
| Polyetherimide | | 3.50 | | 0.00056 | >400 |
| Core Thickness = 0.030 | | | | | seconds |
| N4000-12 | | | | | |
| Polyetherimide | | 3.47 | | 0.0051 | >400 |
| Core Thickness = 0.030 | | | | | seconds |
| N4000-13 | | | | | |

The test results show that circuit boards made in accordance with the invention have superior electrical properties. The dielectric constant, dissipation factor, and pressure cooker solder float results demonstrate that the etched PTFE bond cores and the polyetherimide etched bond cores can be used as a bonding ply in single printed circuit board laminates and multi-ply printed circuit boards, especially those for high speed digital and microwave applications.

While the invention has been specifically described in connection with certain specific embodiments thereof, it is to be understood that this is by way of illustration and not of limitation. Reasonable variation and combination are possible with the scope of the foregoing disclosure without departing from the spirit of the invention which is defined in the appended claims.

1. A printed circuit board laminate comprising
at least one resin-system layer;
a low dielectric, low dissipation factor bond core having at least one surface that is treated to facilitate bonding to the at least one resin system layer; and
a conductive metal cladding on the at least one resin system layer.

2. The printed circuit board laminate according to claim 1 wherein the low dielectric, low dissipation factor bond core is a fluoropolymer film.

3. The printed circuit board laminate according to claim 2, wherein the fluoropolymer film is polytetrafluoroethylene.

4. The printed circuit board laminate according claim 3 wherein the fluoropolymer bond core has two etched surfaces.

5. The printed circuit board laminate according to claim 4 wherein the at least one resin-system layer is an epoxy prepreg.

6. The printed circuit board laminate according to claim 4 wherein the at least one resin-system layer is a resin-coated conductive foil.

7. The printed circuit board laminate according claim 1 wherein the low dielectric, low dissipation factor bond core is an impregnated prepreg.

8. The printed circuit board laminate according to claim 7, wherein the impregnated prepreg is impregnated with polytetrafluoroethylene.

9. The printed circuit board laminate according claim 8 wherein the fluoropolymer bond core has two etched or plasma or Corona discharge treated surfaces.

10. The printed circuit board laminate according to claim 9 wherein the at least one resin-system layer is an epoxy prepreg.

11. The printed circuit board laminate according to claim 9 wherein the at least one resin-system layer is a resin-coated conductive foil.

12. The printed circuit board laminate according claim 1 wherein the low dielectric, low dissipation factor bond core has two etched or plasma or Corona discharge treated surfaces.

13. The printed circuit board laminate according to claim 1 wherein the at least one resin-system layer is an epoxy prepreg.

14. The printed circuit board laminate according to claim 1 wherein the at least one resin-system layer is a resin-coated conductive foil.

15. The printed circuit board laminate according to claim 1 wherein the low dielectric, low dissipation factor bond core comprises polyetherimide.

16. A multi-ply printed circuit board laminate comprising a plurality of printed circuit board laminates according to claim 1 and further including at least one layer of the low dielectric, low dissipation factor bond core and optionally at least one epoxy prepreg between each printed circuit board laminate.

17. A method for making a printed circuit board laminate comprising the steps of:
treating at least one surface of a low dielectric, low dissipation factor bond core layer to render it receptive to bonding to a resin-system layer; and
thereafter applying a resin-system layer to the treated surface of the low dielectric, low dissipation factor bond core layer under sufficient heat and pressure to bond the resin-system layer to the low dielectric, low dissipation factor bond core layer.

18. A method for making a printed circuit board laminate according to claim 17 wherein the resin-system layer has a conductive metal cladding layer laminated thereto.

19. A method for making a printed circuit board laminate according to claim 18 wherein the treating step includes passing the low dielectric, low dissipation factor bond core layer through a bath of a solution which attacks the surface of the polymer.

20. The printed circuit board laminate according to claim 19 wherein the low dielectric, low dissipation factor bond core comprises a fluoropolymer whereby the fluorine is stripped from the surface of the fluoropolymer bond core layer and replaced with at least one of hydroxyl, carbonyl, and carboxyl groups.

21. A method for making a printed circuit board laminate according to claim 20 wherein the low dielectric, low dissipation factor bond core is a fluoropolymer film.

22. A method for making a printed circuit board laminate according to claim 21 wherein the fluoropolymer film is polytetrafluoroethylene.

23. A method for making a printed circuit board laminate according to claim 17 wherein the treating step comprises etching two surfaces of the low dielectric, low dissipation factor bond core, and wherein the resin-system layer applying step comprises applying a resin-system layer to each of the etched surfaces of the low dielectric, low dissipation factor bond core layer.

24. A method for making a printed circuit board laminate according to claim 23 wherein the at least one resin-system layer is an epoxy prepreg.

25. A method for making a printed circuit board laminate according to claim 24 wherein the at least one resin-system layer is a resin-coated conductive foil.

26. A method for making a printed circuit board laminate according to claim 17 wherein the low dielectric, low dissipation factor bond core is an impregnated prepreg.

27. A method for making a printed circuit board laminate according to claim 26 wherein the impregnated prepreg is impregnated with a fluoropolymer.

28. A method for making a printed circuit board laminate according to claim 26 wherein the impregnated prepreg is impregnated with a polyetherimide.

29. A method for making a printed circuit board laminate according to claim 17 wherein the at least one resin-system layer is an epoxy prepreg.

30. A method for making a printed circuit board laminate according to claim 17 wherein the at least one resin-system layer is a resin-coated conductive foil.

31. A method for making a printed circuit board laminate according to claim 17 wherein the low dielectric, low dissipation factor bond core is a fluoropolymer film.

32. A method for making a printed circuit board laminate according to claim 31 wherein the fluoropolymer film is polytetrafluoroethylene.

33. A method for making a printed circuit board laminate according to claim 17 wherein the low dielectric, low dissipation factor bond core is a fluoropolymer impregnated prepreg.

34. A method for making a printed circuit board laminate according to claim 33 wherein the fluoropolymer impregnated prepreg is impregnated with polytetrafluoroethylene.

35. A method for making a printed circuit board laminate according to claim 31 wherein the treating step includes passing the fluoropolymer film through a bath of a solution which attacks the fluorine in the polymer, whereby the fluorine is stripped from the surface of the fluoropolymer film and replaced with at least one of hydroxyl, carbonyl, and carboxyl groups.

36. A method for making a printed circuit board laminate according to claim 17 wherein the treating step comprises applying to the at least one surface of the low dielectric, low dissipation factor bond core layer a plasma or Corona discharge treatment.

37. A method for making a printed circuit board laminate according to claim 36 wherein the resin-system layer has a conductive metal cladding layer laminated thereto.

38. A method for making a printed circuit board laminate according to claim 37 wherein the low dielectric, low dissipation factor bond core comprises a fluoropolymer.

39. A method for making a printed circuit board laminate according to claim 38 wherein the fluoropolymer is polytetrafluoroethylene.

40. A method for making a printed circuit board laminate according to claim 37 wherein the low dielectric, low dissipation factor bond core comprises polyetherimide.

41. A method for making a printed circuit board laminate according to claim 36 wherein the at least one resin-system layer is an epoxy prepreg.

42. A method for making a printed circuit board laminate according to claim 41 wherein the low dielectric, low dissipation factor bond core comprises polyetherimide.

43. A method for making a printed circuit board laminate according to claim 36 wherein the at least one resin-system layer is a resin-coated conductive foil.

44. A method for making a printed circuit board laminate according to claim 17 wherein the low dielectric, low dissipation factor bond core is a fluoropolymer impregnated prepreg.

45. A method for making a printed circuit board laminate according to claim 44 wherein the fluoropolymer impregnated prepreg is impregnated with polytetrafluoroethylene.

46. A method for making a printed circuit board laminate according to claim 17 wherein the low dielectric, low dissipation factor bond core comprises polyetherimide.

47. The printed circuit board laminate according to claim 17 wherein the treating step comprises mechanically brushing the surface of the fluoropolymer or polyetherimide bond core.
